(19) United States
(12) Patent Application Publication
(10) Pub. No.: US 2008/0099858 A1
(43) Pub. Date: May 1, 2008

(54) SEMICONDUCTOR DEVICE AND MANFACTURING METHOD OF THE SAME

(75) Inventor: Keizo KAWAKITA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 11/930,453

(22) Filed: Oct. 31, 2007

(30) Foreign Application Priority Data
Nov. 1, 2006 (JP) 2006-297570

(51) Int. Cl. H01L 29/78; H01L 21/20

(52) U.S. Cl. 257/401; 438/507; 257/E29.255; 257/E21.09

(57) ABSTRACT

After forming a fin portion to be active region, openings are formed at portions corresponding to channel portions in a gate dielectric film 22 and a silicon nitride film 23 which cover the fin portion. Exposed surfaces of the silicon substrate 21 in the openings are oxidized to form oxide films 28. Then the oxide films 28 are removed. Hereby, the potions to be the channel portions of the fin portion are selectively reduced in width.

This application is based upon and claims the benefit of priority from Japanese application No. 2006-297570, filed on Nov. 1, 2006, the disclosure of which is incorporated herein in its entirety by reference.

### BACKGROUND OF THE INVENTION

This invention relates to a semiconductor device and a manufacturing method thereof and, in particular, relates to a semiconductor device having fin field effect transistor (FET) structure and a manufacturing method thereof.

In a related semiconductor device having fin FET structure, an active region has a rectangular shape when it is shown from a surface side of a substrate. That is, in the related semiconductor device having the fin FET structure, the active region is formed to have a fixed width because portions for source and drain are not distinguished from a portion for a channel between the source and the drain. This is due to simplification of manufacturing, limit of lithography or the like. Further, this is because it is unnecessary to vary their widths. Such a semiconductor device is disclosed in Japanese Unexamined Patent Application Publication (JP-A) No. 2005-229101.

### SUMMARY OF THE INVENTION

Recently, as a technique for achieving higher integration and lower power consumption, attention is paid to fully-depleted silicon on insulator (FDSOI) technique. To apply such a technique to a fin field effect transistor (FET), it is necessary to reduce a width of a channel region to about 30 nm. Aforementioned patent publication shows that a width of a fin-shaped active region is smaller than 100 nm. However, the document merely shows an example of 80 nm, which is considerably larger than 30 nm.

In a related semiconductor device having a fin FET structure, an active region is formed so that a width of a channel portion of the active region is equal to those of source and drain. Accordingly, if the width of the channel is reduced, widths of the source and the drain are inevitably reduced.

On each of the source and the drain, a contact plug is formed to be electrically coupled with a wiring line. When the width of the source or the drain is reduced, a contact area between the contact plug and the source or drain is reduced and thereby increasing a contact resistance between the source or drain and the contact plug. As a result, an on-current Iₒₙ flowing through a fin FET is restricted.

Thus, the related semiconductor device having the fin FET structure has a problem that the on-current flowing through the transistor is restricted when the FDSOI technique is applied.

It is therefore an object of this invention to provide a semiconductor device having a fin FET structure which permits a sufficient on-current to flow through a transistor even if FDSOI technique is applied, and to provide a manufacturing method thereof.

According to a first aspect of this invention, a semiconductor device includes an active region having a fin shape. In the semiconductor device, a width of a portion to be a channel portion of the active region is smaller than widths of portions to be source or drain of the active region.

According to another aspect of this invention, a manufacturing method of a semiconductor device which includes an active region of a fin shape is provided. The method includes the steps of: forming a fin portion having a fixed width to be the active region; and partly reducing a width of a portion to be a channel portion of the fin portion.

### BRIEF DESCRIPTION OF THE DRAWINGS

FIG. 1 is plan view showing a layout structure of a cell of a dynamic random access memory (DRAM) according to a first embodiment of this invention;

FIGS. 2A, 2B and 2C are a sectional view taken along an A-A′ line of FIG. 1, a sectional view taken along a B-B′ line of FIG. 1, and a sectional view taken along a C-C′ line of FIG. 1, respectively, for describing one process of a DRAM manufacturing method according to the first embodiment of the invention;

FIGS. 3A, 3B and 3C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 2A-2C;

FIGS. 4A, 4B and 4C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 3A-3C;

FIGS. 5A, 5B and 5C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 4A-4C;

FIGS. 6A, 6B and 6C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 5A-5C;

FIGS. 7A, 7B and 7C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 6A-6C;

FIGS. 8A, 8B and 8C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 7A-7C;

FIGS. 9A, 9B and 9C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 8A-8C;

FIGS. 10A, 10B and 10C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 9A-9C;

FIGS. 11A, 11B and 11C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 10A-10C;

FIGS. 12A, 12B and 12C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 11A-11C;

FIGS. 13A, 13B and 13C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 12A-12C;

FIG. 14 is a plan view showing six arranged fin portions which are formed by the process of FIG. 13A-13C;

FIG. 15 is a plan view showing a positional relationship between the six fin portions of FIG. 14 and gate electrodes;

FIGS. 16A, 16B and 16C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 13A-13C;

FIGS. 17A, 17B and 17C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 16A-16C;

FIGS. 18A, 18B and 18C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 17A-17C;

FIGS. 19A, 19B and 19C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 18A-18C;

FIGS. 20A, 20B and 20C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 19A-19C;

FIGS. 21A, 21B and 21C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 20A-20C;

FIGS. 22A, 22B and 22C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 21A-21C;

FIGS. 23A, 23B and 23C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 22A-22C;

FIGS. 24A, 24B and 24C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 23A-23C;

FIGS. 25A, 25B and 25C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process of a DRAM manufacturing method according to the second embodiment of the invention;

FIGS. 26A, 26B and 26C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 25A-25C;

FIGS. 27A, 27B and 27C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 26A-26C;

FIGS. 28A, 28B and 28C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 27A-27C;

FIGS. 29A, 29B and 29C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 28A-28C;

FIGS. 30A, 30B and 30C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 29A-29C;

FIGS. 31A, 31B and 31C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 30A-30C;

FIGS. 32A, 32B and 32C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 31A-31C;

FIGS. 33A, 33B and 33C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 32A-32C;

FIGS. 34A, 34B and 34C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 33A-33C;

FIGS. 35A, 35B and 35C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 34A-34C;

FIGS. 36A, 36B and 36C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 35A-35C;

FIGS. 37A, 37B and 37C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 36A-36C;

FIGS. 38A, 38B and 38C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 37A-37C;

FIGS. 39A, 39B and 39C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 38A-38C;

FIGS. 40A, 40B and 40C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process of a DRAM manufacturing method according to a third embodiment of this invention;

FIGS. 41A, 41B and 41C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 40A-40C;

FIGS. 42A, 42B and 42C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 41A-41C;

FIGS. 43A, 43B and 43C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 42A-42C;

FIGS. 44A, 44B and 44C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 43A-43C;

FIGS. 45A, 45B and 45C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 44A-44C;

FIGS. 46A, 46B and 46C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 45A-45C;

FIGS. 47A, 47B and 47C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 46A-46C;

FIGS. 48A, 48B and 48C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 47A-47C;

FIGS. 49A, 49B and 49C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 48A-48C;

FIGS. 50A, 50B and 50C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 49A-49C;

FIGS. 51A, 51B and 51C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 50A-50C;

FIGS. 52A, 52B and 52C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 51A-51C;

FIGS. 53A, 53B and 53C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 52A-52C;

FIGS. 54A, 54B and 54C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 53A-53C;

FIGS. 55A, 55B and 55C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 54A-54C;

FIGS. 56A, 56B and 56C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 55A-55C;

FIGS. 57A, 57B and 57C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 56A-56C;

FIGS. 58A, 58B and 58C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process of a DRAM manufacturing method according to a fourth embodiment of this invention;

FIGS. 59A, 59B and 59C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 58A-58C;

FIGS. 60A, 60B and 60C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 59A-59C;

FIGS. 61A, 61B and 61C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 60A-60C;

FIGS. 62A, 62B and 62C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 61A-61C;

FIGS. 63A, 63B and 63C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 62A-62C;

FIGS. 64A, 64B and 64C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 63A-63C;

FIGS. 65A, 65B and 65C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 64A-64C;

FIGS. 66A, 66B and 66C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 65A-65C;

FIGS. 67A, 67B and 67C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 66A-66C;

FIGS. 68A, 68B and 68C are a sectional view corresponding to that taken along the A-A′ line of FIG. 1, a sectional view corresponding to that taken along the B-B′ line of FIG. 1, and a sectional view corresponding to that taken along the C-C′ line, respectively, for describing one process subsequent to the process of FIG. 67A-67C; and

FIG. 69 is a plan layout view for describing a memory cell structure of 6F².

### DESCRIPTION OF THE PREFERRED EMBODIMENTS

Hereinafter, preferred embodiments of this invention will be minutely described with reference to the drawings.

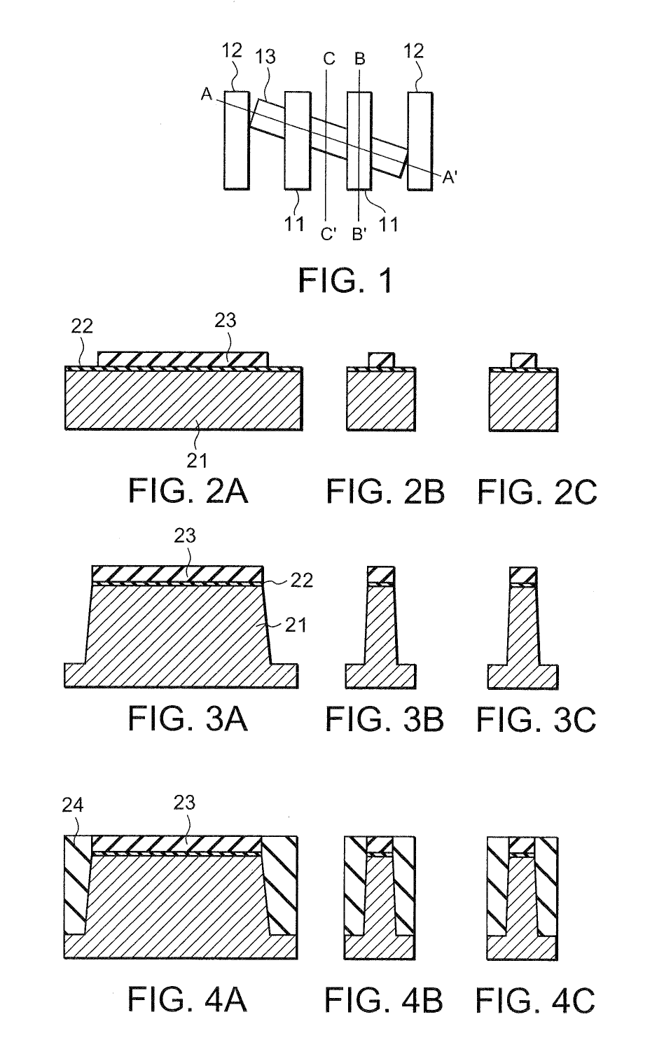

At first, referring to FIGS. 1 to 24C, the description will be made about a method for manufacturing a semiconductor device (or a dynamic random access memory: DRAM) according to a first embodiment of this invention.

FIG. 1 is a plan view showing a layout structure of a cell (twin cells) of a DRAM according to the first embodiment. In a practical DRAM, a large number of cells are regularly (or periodically) arranged.

In FIG. 1, plural gate electrode regions 11 and 12 are delimited to be parallel with one another at regular intervals and to be extended along an up and down direction. An active region 13 is delimited to have a predetermined angle with respect to the gate electrode regions 11 and 12. At the two gate electrode regions 11 intersecting with the active region 13, gate electrodes (or word lines) are formed to be used for cell transistors (here, a fin FETs) formed in the active region 13. At the remaining gate electrode regions 12 which do not intersect with the active region 13, dummy gate electrodes are formed.

Intersection portions of the active region 13 intersecting with the gate electrode regions 11 become channel portions (or path gates) of the FETs. End portions of the active region 13 in a longitudinal direction (or a right and left direction of FIG. 1) at outsides of the channel portions become storage node contact portions (or sources). A middle portion of the active region 13 between the two channel portions becomes a bit line contact portion (or a drain). For example, a bit line not shown is formed along the right and left direction of FIG. 1 to be at right angle to the gate electrodes.

FIGS. 2A to 13C and 16A to 24C show a series of manufacturing processes, wherein FIGS. 2A, 3A, . . . , 13A, 16A, 17A, . . . , 24A each show (A) a sectional view corresponding to that taken along an A-A′ line of FIG. 1 in each process, FIGS. 2B, 3B, . . . , 13B, 16B, 17B, . . . , 24B each show (B) a sectional view corresponding to that taken along a B-B′ line of FIG. 1 in each process, and FIGS. 2C, 3C, . . . , 13C, 16C, 17C, . . . , 24C each show (C) a sectional view corresponding to that taken along a C-C′ line of FIG. 1 in each process. In other words, FIGS. 2A, 3A, . . . , 13A, 16A, 17A, . . . , 24A each show (A) the sectional view in a long-side direction of the active region 13, FIGS. 2B, 3B, 13B, 16B, 17B, . . . , 24B each show (B) the sectional view in a width direction of the bit line contact portion of the active region, and FIGS. 2C, 3C, . . . , 13C, 16C, 17C, . . . , 24C each show (C) the sectional view in the width direction of the channel portion of the active region. Hereinafter, a term “width” signifies length in a direction perpendicular to the long-side direction in the plan view (seen from a surface side of a substrate or an upper side of a stacking direction) as far as the active region 13 is concerned.

Thereinafter, the manufacturing method of the DRAM according to the first embodiment is described with referring to FIGS. 2A to 24C.

First, a silicon substrate 21 (FIGS. 2A-2C) is provided and a gate dielectric film 22 (FIGS. 2A-2C) (e.g. 13 nm thickness) is deposited or formed by thermal oxidation. Subsequently, a silicon nitride film 23 (FIGS. 2A-2C) (e.g. 120 nm thickness) is formed on the gate dielectric film 22. Further, a resist pattern (not shown) is formed at a region corresponding to the active region 13 (FIG. 1) on the silicon nitride film 23 using known lithography technique. Then, the silicon nitride film 23 is dry-etched using the resist pattern as a mask. Thereafter, the resist pattern is removed. FIGS. 2A, 2B and 2C shows the state after the processes mentioned above are executed.

Next, as illustrated in FIGS. 3A, 3B and 3C, the gate dielectric film 22 and the silicon substrate 21 are etched, for example, by 300 nm using the silicon nitride film 23 as a mask. Hereby, a fin portion to be the active region with a fixed width is formed.

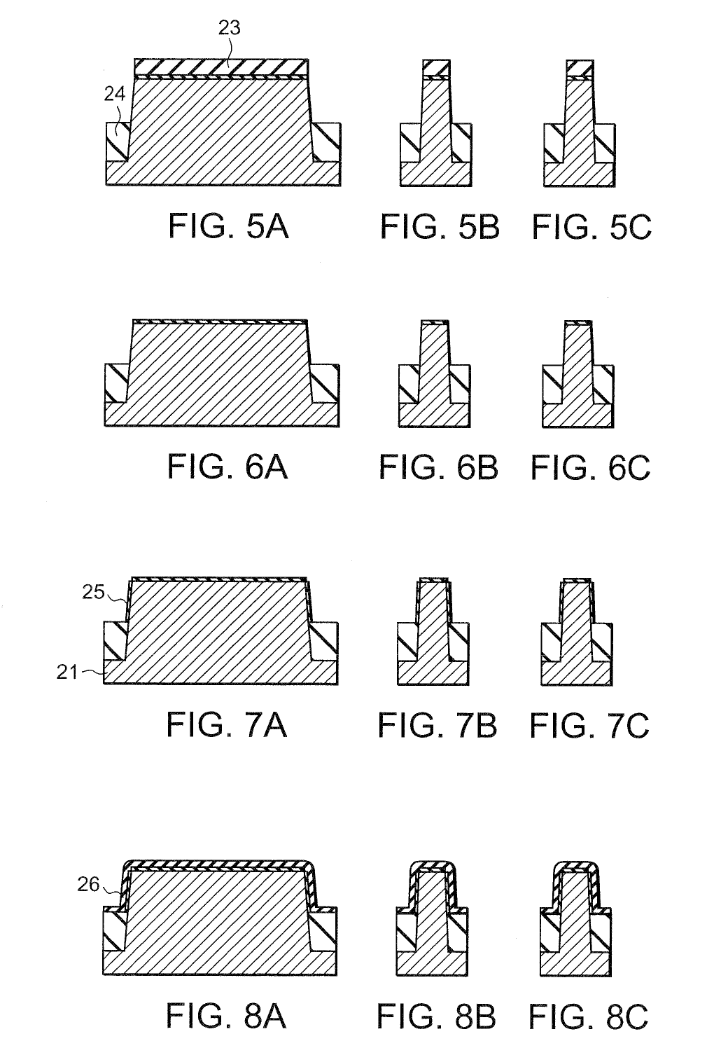

Next, as illustrated in FIGS. 4A, 4B and 4C, a silicon oxidation film 24 is deposited, for example, by 350 nm and polished by chemical mechanical polishing (CMP) to expose an upper surface of the silicon nitride film 23. Moreover, as illustrated in FIGS. 5A, 5B and 5C, a part of the silicon oxide film 24 is removed by, for example, 200 nm by anisotropic etching or etch back.

Next, as shown in FIGS. 6A, 6B and 6C, the silicon nitride film 23 is removed using, for example, phosphoric acid.

Then, as illustrated in FIGS. 7A, 7B and 7C, a silicon oxide film 25 is formed, for example, by 13 nm by oxidizing the exposed surface of the silicon substrate 21. Thereafter, impurities are implanted to form a well using an ion implantation method.

Next, as illustrated in FIGS. 8A, 8B and 8C, a silicon nitride film 26 is deposited on the entire surface, for example, by 30 nm.

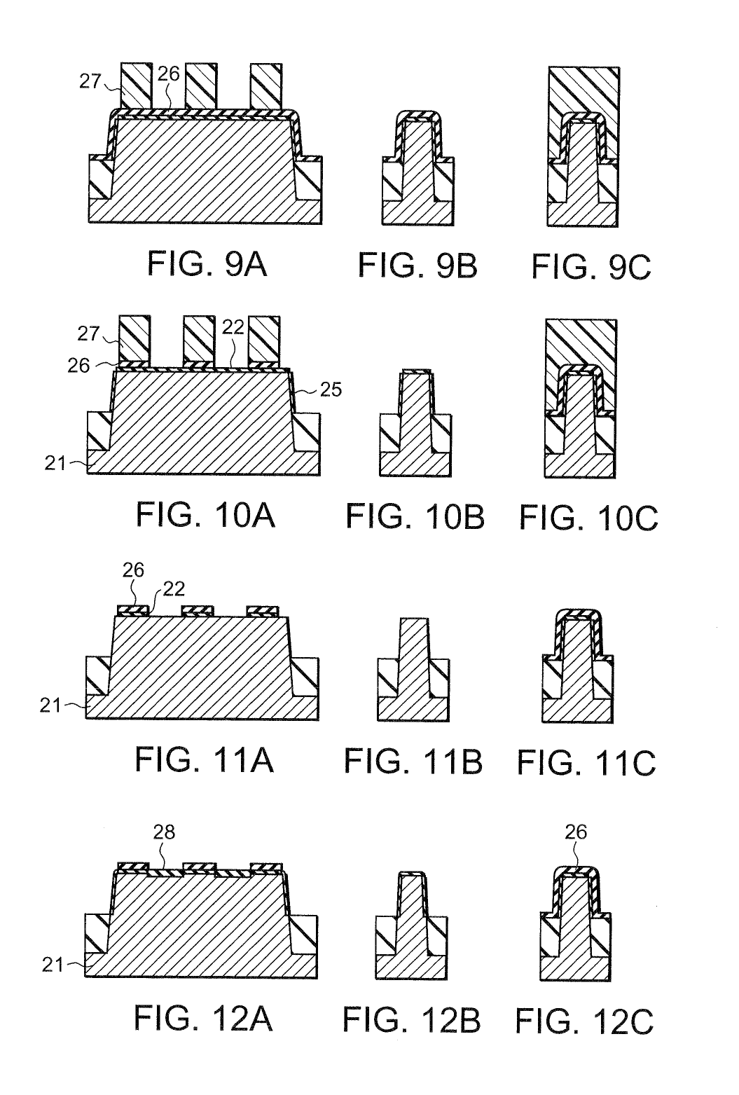

Next, as illustrated in FIGS. 9A, 9B and 9C, a resist pattern 27 is formed to define openings for gate electrode formation regions of the fin FETs and for dummy gate formation regions using known lithography technique. A space between stripes of the resist pattern 27 is equal to 45 nm, for example.

Subsequently, as illustrated in FIGS. 10A, 10B and 10C, the silicon nitride film 26 is etched using the resist pattern 27 as an etching mask. After the resist pattern 27 is removed, the gate dielectric film 22 and the oxidation film 25 are etched using the patterned silicon nitride film 26 as a mask. Thus, the state shown in FIGS. 11A, 11b and 11C is obtained. That is, openings are selectively formed at portions corresponding to the channel portions in the gate dielectric film 22, the silicon oxidation film 25 and silicon nitride film 26 which cover the surface of the fin portion.

Next, as illustrated in FIGS. 12A, 12B and 12C, thermal oxidation films 28 are selectively formed, for example, by 10 nm each on the exposed surfaces of the substrate 21 in the openings of the gate dielectric film 22, the silicon oxidation film 25 and the silicon nitride film 26 by thermal oxidation. As a result, as shown in FIG. 12B, the thermal oxidation films 28 covers the upper and the side surfaces at the portions to be the channel portions of the fin FETs. On the other hand, since the portion to be the bit line contact portion (and the storage node contacts) is covered by the silicon nitride film 26 as shown in FIG. 12C, no thermal oxidation film is formed at there.

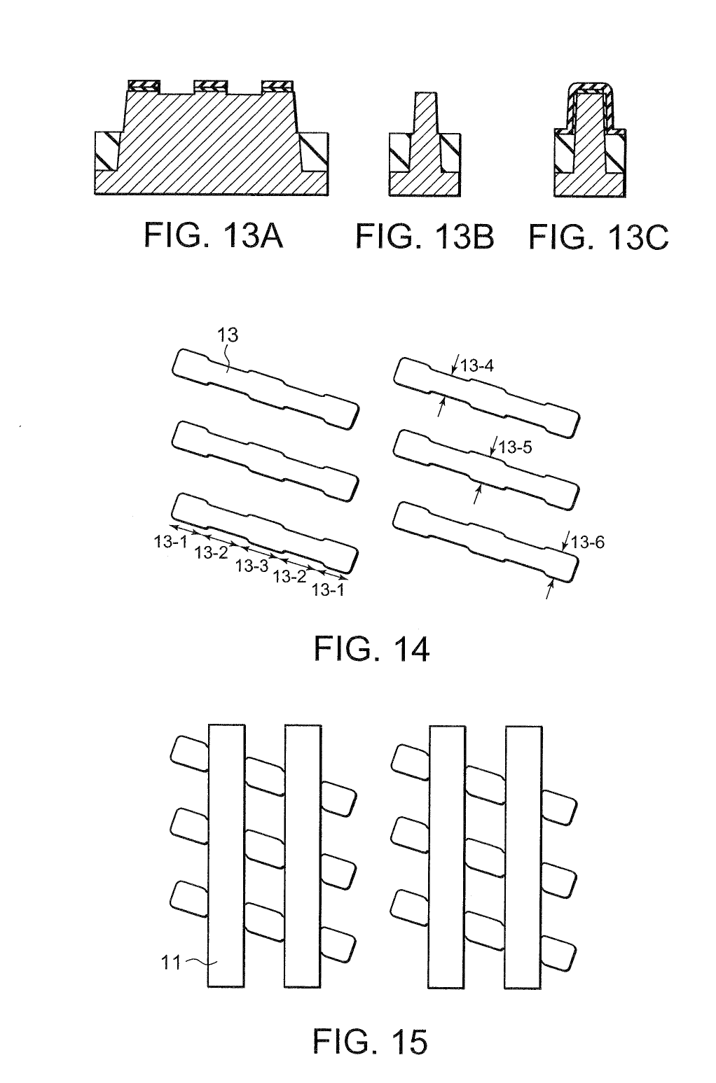

Next, as illustrated in FIGS. 13A, 13b and 13C, the thermal oxidation films 28 are removed by chemical dry etching or diluted hydrofluoric acid. As mentioned above, the thermal oxidation films 28 are formed at the portions to be the channel portions of the active region and not formed at the portions to be bit line contact portion and the storage node contact portions. Accordingly, by removing the thermal oxidation films 28, the width of the active region is selectively reduced at the channel portions. Thus, there is obtained a structure that widths of the channel portions are smaller than widths of the bit line contact portion and the storage node contact portions.

FIG. 14 is a plan view showing the state of the fin portions (or six arranged active regions) after the thermal oxidation films 28 are removed. As shown in FIG. 14, in each active region 13, the portions 13-1 to be the storage node contact portions, the portions 13-2 to be the channel portions of the fin FETs and the portion 13-3 to be the bit line contact portion have widths 13-6, 13-4 and 13-5, respectively. The widths 13-6 and 13-5 of the portions 13-1 and 13-3 are wider than the width 13-4 of the portion 13-2. Additionally, gate electrodes are formed in the gate electrode regions 11 later as shown in FIG. 15.

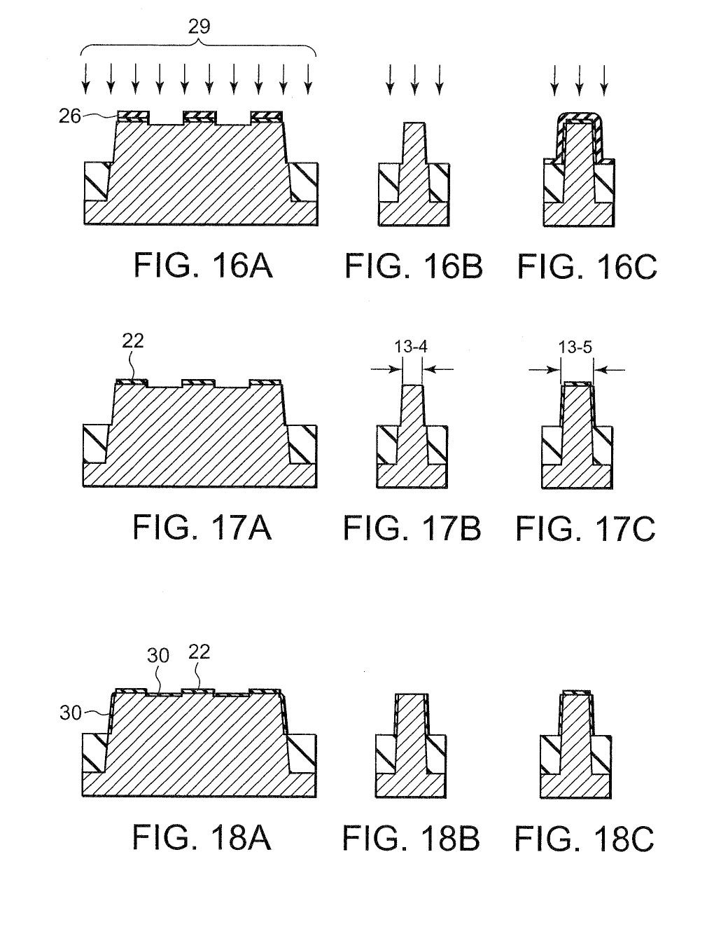

After the thermal oxidation films 28 are removed, as illustrated in FIGS. 16A, 16B and 16C, ion implantation is performed to introduce impurities 29 only in the regions (or the channel portions) which is not covered with the silicon nitride film 26. The impurities 29 are boron and its density is equal to 1E12 cm⁻³, for example.

Next, as illustrated in FIGS. 17A, 17B and 17C, the silicon nitride film 26 is removed by chemical dry etching or diluted hydrofluoric acid.

Next, as illustrated in FIGS. 18A, 18B and 18C, the exposed surfaces of the substrate 21 are oxidized to form gate oxide films 30 (e.g. 6 nm thickness each). Further, an azotizing process using plasma is applied to the gate oxide films 30 to change the surfaces of the oxide films 30 into oxynitride films (e.g. 3 nm thickness each). Incidentally, high temperature oxide (HTO) films or high dielectric constant films may be used as a substitute for the gate oxide films 30 and the oxynitride films.

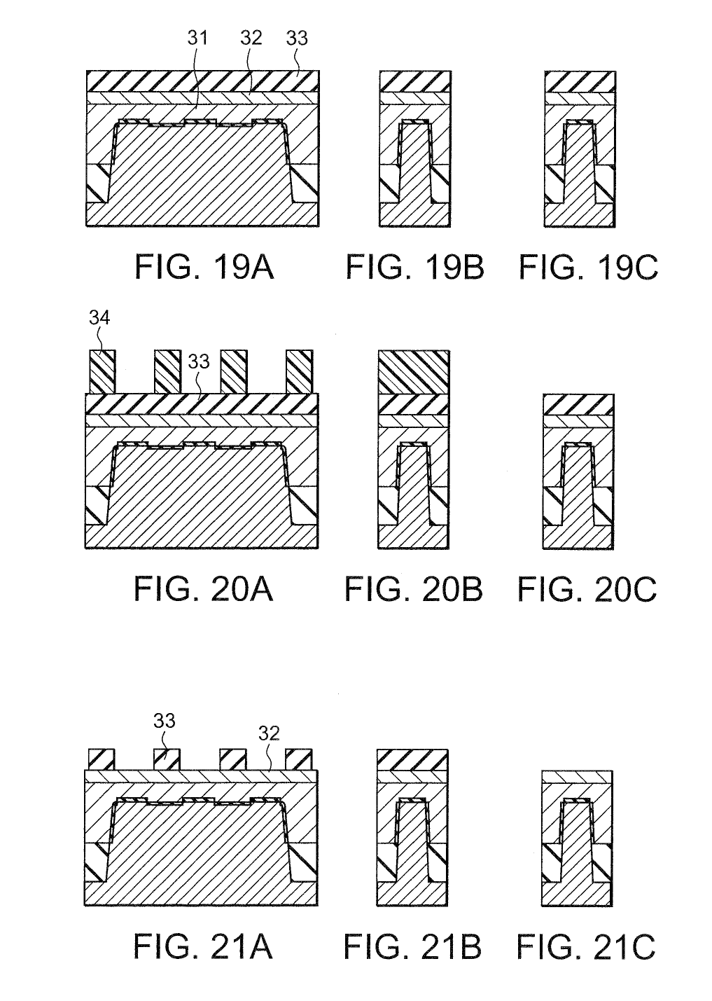

Next, as illustrated in FIGS. 19A, 19B and 19C, a gate electrode polysilicon layer 31 is formed and then the surface thereof is flattened to have a thickness of 60 nm at an upside of the gate dielectric film 22 for example. Subsequently, a stacked film 32 consisting of a tungsten silicide film (e.g. 5 nm thickness), a tungsten nitride film (e.g. 10 nm thickness) and a tungsten film (e.g. 100 nm thickness) and a silicon nitride film 33 (e.g. 100 nm thickness) are sequentially stacked.

Next, as illustrated in FIGS. 20A, 20B and 20C, a resist pattern 34 is formed at regions corresponding to the gate electrode portions and to the dummy gate portions on the silicon nitride film 33. Here, a space between stripes of the resist pattern 34 is equal to 55 nm for example.

Next, as illustrated in FIGS. 21A, 21B and 21C, the silicon nitride film 33 is etched using the resist pattern 34 as a mask and then the resist pattern 34 is removed.

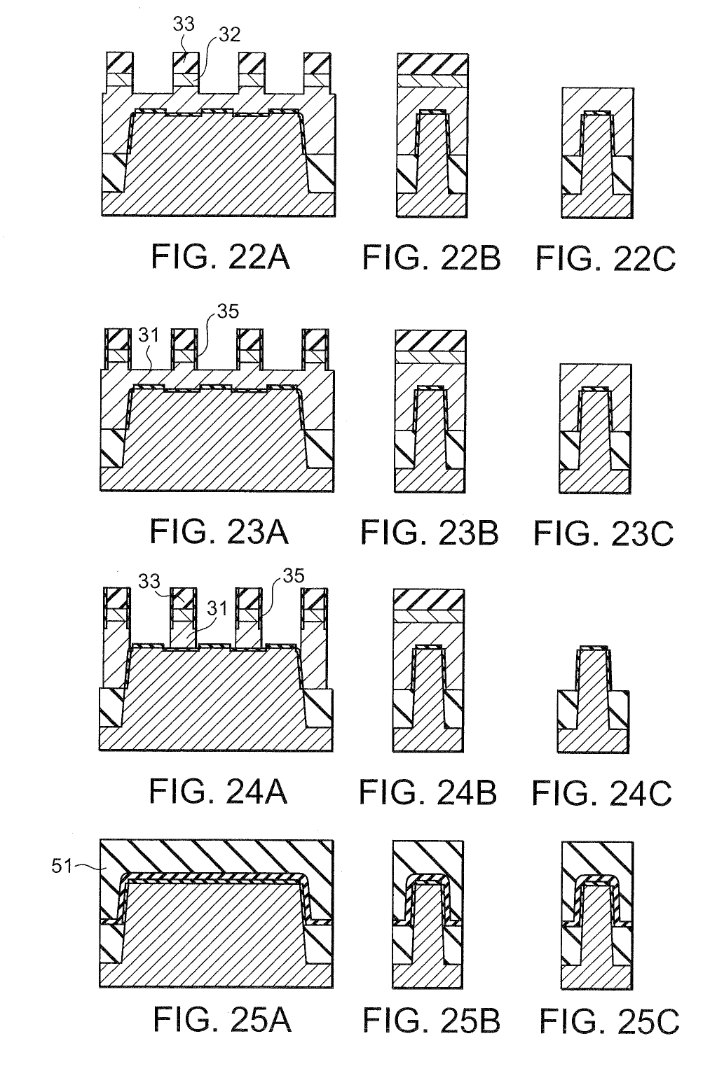

Next, as illustrated in FIGS. 22A, 22B and 22C, the stacked film 32 consisting of the tungsten film, the tungsten nitride film and the tungsten silicide film is etched using the remaining parts of the silicon nitride film 33 as a mask.

Next, a silicon nitride is disposed, for example, by 15 nm and etched back by dry etching to form sidewalls 35 as shown in FIGS. 23A, 23B and 23C.

Next, as illustrated in FIGS. 24A, 24B and 24C, the polysilicon layer 31 is etched using the silicon nitride film 33 and the sidewalls 35 as a mask.

After that, known processes for a DRAM are performed to form capacitors and wiring lines or the like and thereby completing the DRAM.

As mentioned above, according to the first embodiment, it is possible to manufacture a semiconductor device (DRAM) having a fin FET with an active region in which a storage node contact portion and a bit line contact portion are lager than a channel portion in width. Hereby, even if a width of the channel portion is reduced to a necessary width (e.g. 30 nm) to be fully depleted, the storage node contact portion and the bit line contact portion secure enough widths (e.g. 50 nm) to suppress increasing contact resistance. That is, according to the first embodiment, there is obtained a semiconductor device having a fin FET (or a DRAM having twin cells) in which the channel portion can be fully depleted and sufficient on current can flow therethrough.

Furthermore, according to the embodiment, since some processes are merely added in comparison with the prior art, the DRAM having the aforementioned structure can be manufactured with a little rise of manufacturing cost.

Referring to FIGS. 25A to 39C, the description will be made about a second embodiment of this invention.

At first, the state of FIGS. 8A-8C is obtained by performing the same processes as those (shown FIGS. 2A-8C) of the first embodiment.

Subsequently, as illustrated in FIGS. 25A, 25B and 25C, a silicon oxide film 51 (e.g. 100 nm thickness) is deposited and then polished, for example, by 20 nm by CMP to be flattened.

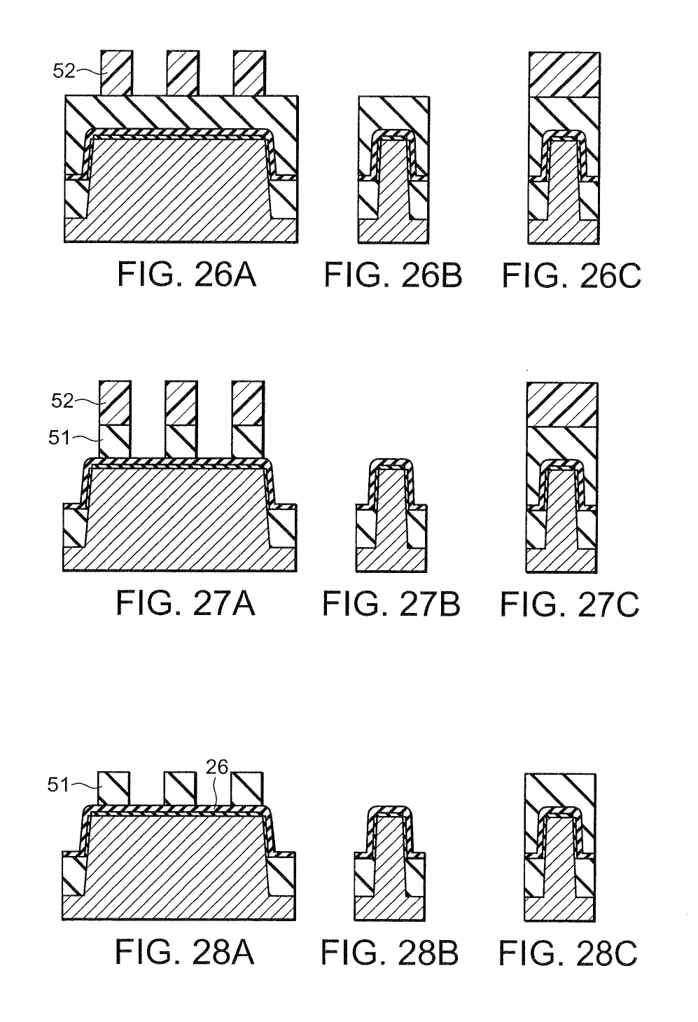

Next, as illustrated in FIGS. 26A, 26B and 26C, a resist pattern 52 is formed to define openings for gate electrode regions of the fin FETs and for dummy gate regions using known lithography technique. A space between stripes of the resist pattern 52 is equal to 45 nm, for example.

Next, as illustrated in FIGS. 27A, 27B and 27C, the silicon oxide film 51 is etched using the resist pattern 52 as a mask. Thereafter, as illustrated in FIGS. 28A, 28B and 28C, the resist pattern 52 is removed.

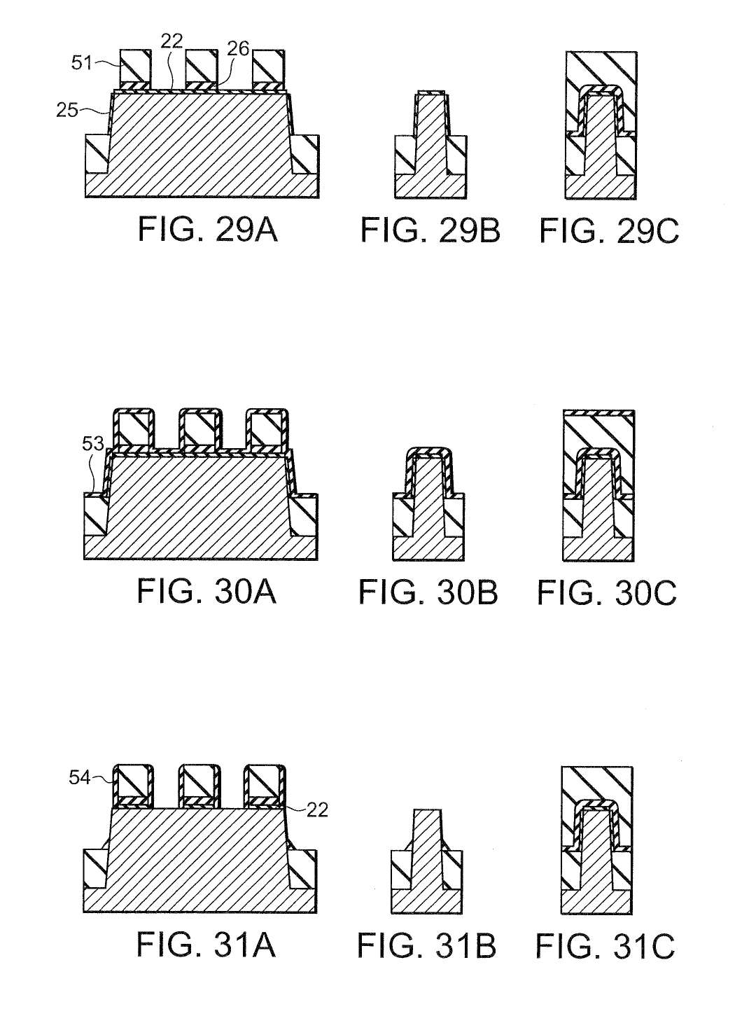

Next, as illustrated in FIGS. 29A, 29B and 29C, the silicon nitride film 26 is processed by anisotropic etching using the silicon oxide film 51 as a mask.

Next, as illustrated in FIGS. 30A, 30B and 30C, a silicon nitride film 53 is deposited, for example, by 10 nm. Then, as illustrated in FIGS. 31A, 31B and 31C, the silicon nitride film 53 is processed by anisotropic etching to form sidewalls 54 in the form of the silicon nitride film 53 on side walls of the remaining silicon oxide films 51. In this event, a part of the gate dielectric film 22 and the silicon oxide film 25 are also etched. Thus, openings are formed in the gate dielectric film 22, the silicon oxide film 25 and the silicon nitride film 53 which are formed over the fin portion.

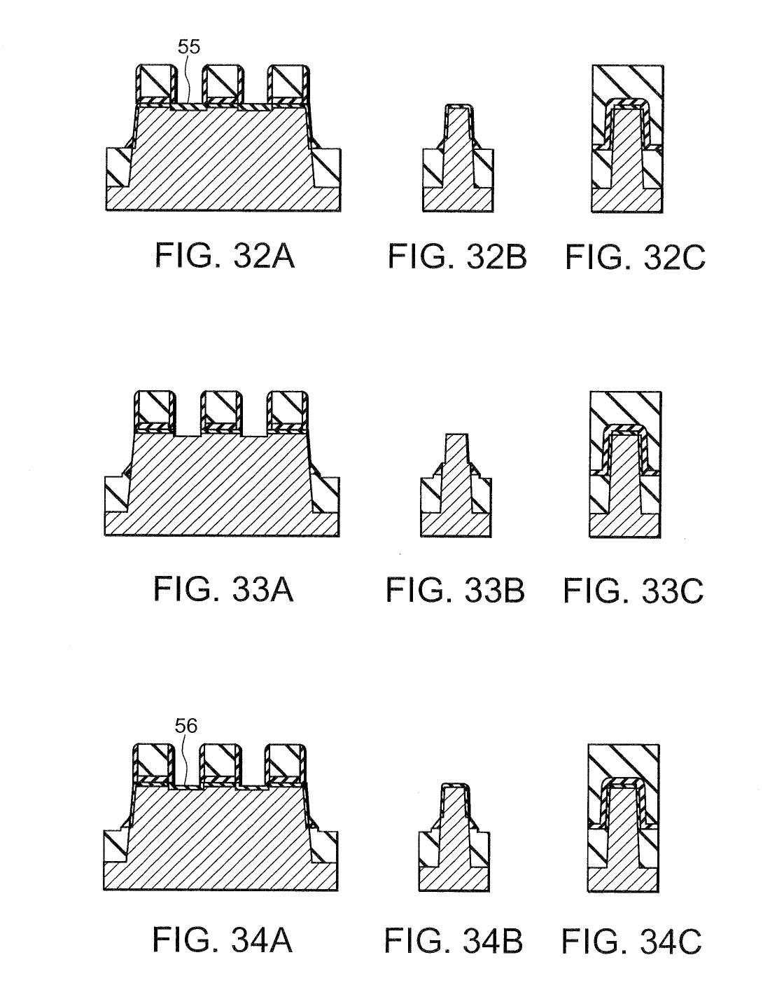

Next, exposed surfaces of the silicon substrate 21 in the openings are selectively oxidized by thermal oxidization to form silicon oxide films 55 (e.g. 10 nm thickness each) as illustrated in FIGS. 32A, 32B and 32C.

Next, as illustrated in FIGS. 33A, 33B and 33C, the silicon oxide films 55 are removed by chemical dry etching or diluted hydrofluoric acid. Hereby, similarly as for the first embodiment, widths of the channel portions of the active region can be selectively narrowed than widths of the storage node contact portions and width of the bit line contact portion.

Next, as illustrated in FIGS. 34A, 34B and 34C, the exposed surfaces of the silicon substrate 21 are oxidized to form gate oxide films 56 (e.g. 6 nm thickness each). Then, the surfaces of the gate oxide films 56 are changed into oxynitride films (e.g. 3 nm thickness each) by an azotizing process using plasma. Incidentally, high temperature oxide (HTO) films or high dielectric constant films may be used as a substitute for the gate oxide films 56 and the oxynitride films.

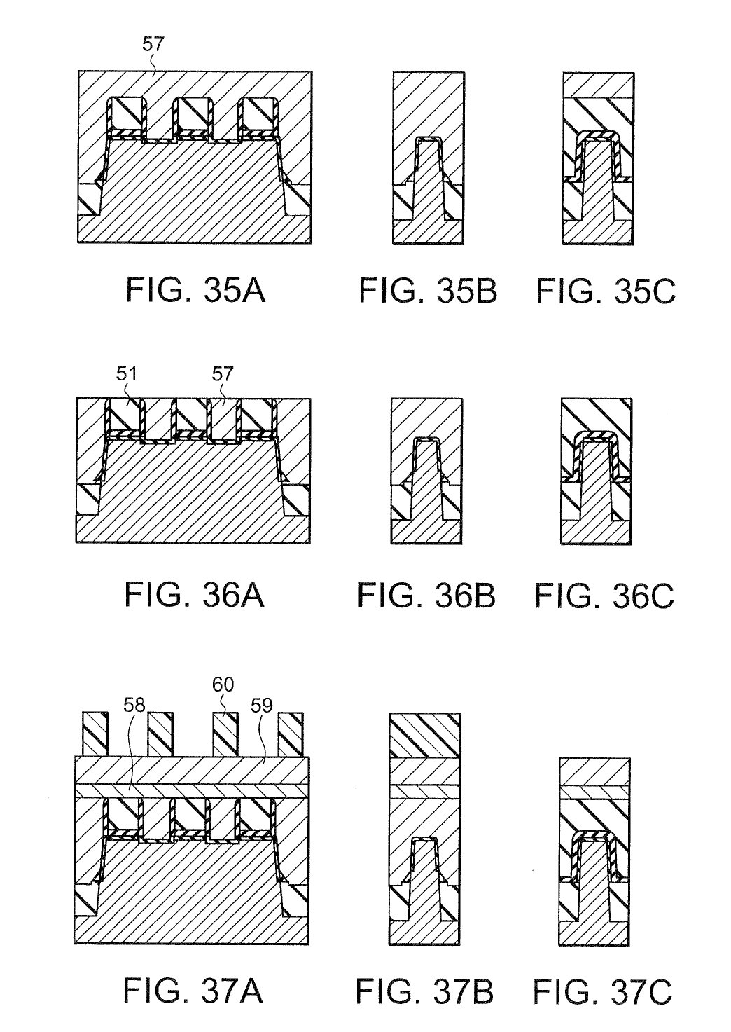

Next, as illustrated in FIGS. 35A, 35B and 35C, a gate electrode polysilicon layer 57 is deposited by 40 nm or more (e.g. 100 nm thickness) for example. Additionally, it is preferable that the polysilicon layer 57 includes boron, which is doped therein, of 2E20 cm⁻³ (in-situ) or more.

Next, as illustrated in FIGS. 36A, 36B and 36C, the gate electrode polysilicon layer 57 is polished to expose the silicon oxide film 51 by CMP.

Next, as illustrated in FIGS. 37A, 37B and 37C, a stacked film 58 consisting of a tungsten silicide film (e.g. 5 nm thickness), a tungsten nitride film (e.g. 10 nm thickness) and a tungsten film (e.g. 55 nm thickness) is formed. Moreover, a silicon nitride film 59 (e.g. 100 nm thickness) is disposed on the stacked layer 58. Furthermore, by known lithography technique, a resist pattern 60 is formed at portions corresponding to the gate electrode portions and the dummy gate potions on the silicon nitride film 59.

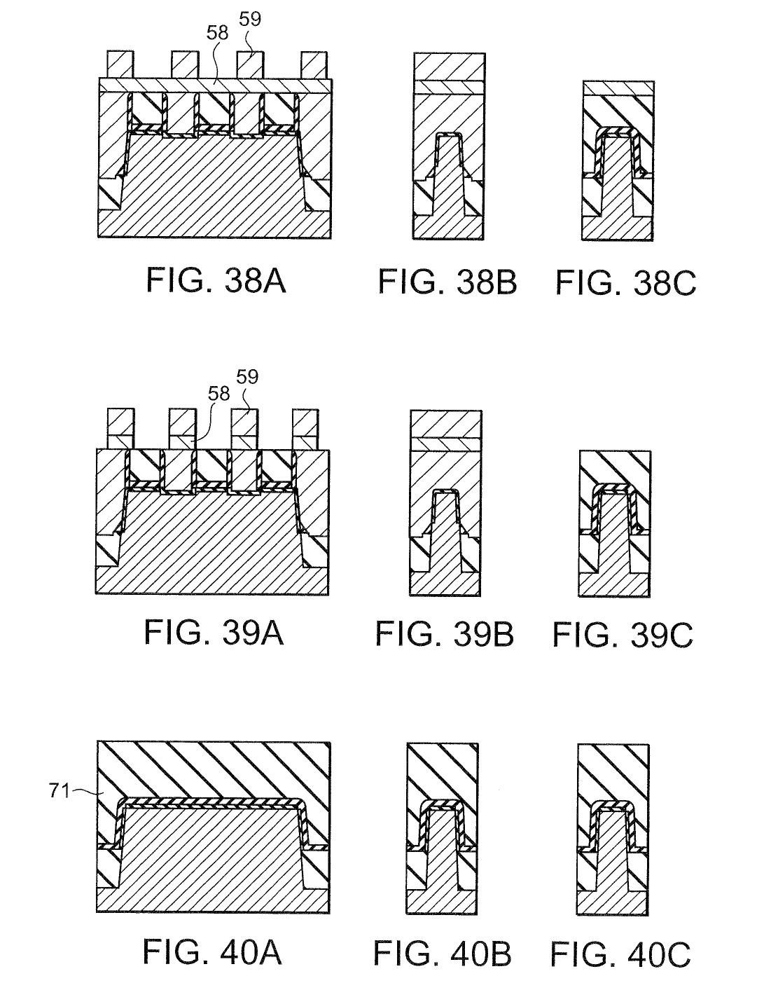

Next, as illustrated in FIGS. 38A, 38B and 38C, the silicon nitride film 59 is etched using the resist pattern 60 as a mask and then the resist pattern 60 is removed.

Next, as illustrated in FIGS. 39A, 39B and 39C, the stacked film 58 consisting of the tungsten film, the tungsten nitride film and the tungsten silicide film is dry etched using the silicon nitride film 59 as a mask.

After that, known processes for a DRAM are performed to form capacitors and wiring lines or the like and thereby completing the DRAM.

As mentioned above, according to the second embodiment, it is possible to manufacture a semiconductor device (DRAM) in the same way as the first embodiment. The semiconductor device has a fin FET with an active region in which a storage node contact portion and a bit line contact portion are lager than a channel portion in width. Hereby, there is obtained a semiconductor device (or a DRAM having twin cells) having a fin FET in which the channel portion can be fully depleted and sufficient on current can flow therethrough. Moreover, the manufacturing cost hardly rises.

Referring to FIGS. 40A to 57C, the description will be made about a third embodiment of this invention.

At first, the state of FIGS. 8A-8C is obtained by performing the same processes as those (shown FIGS. 2A-8C) of the first embodiment.

Afterwards, as illustrated in FIGS. 40A, 40B and 40C, a silicon oxide film 71 (e.g. 200 nm thickness) is formed and then polished by, for example, 20 nm by CMP.

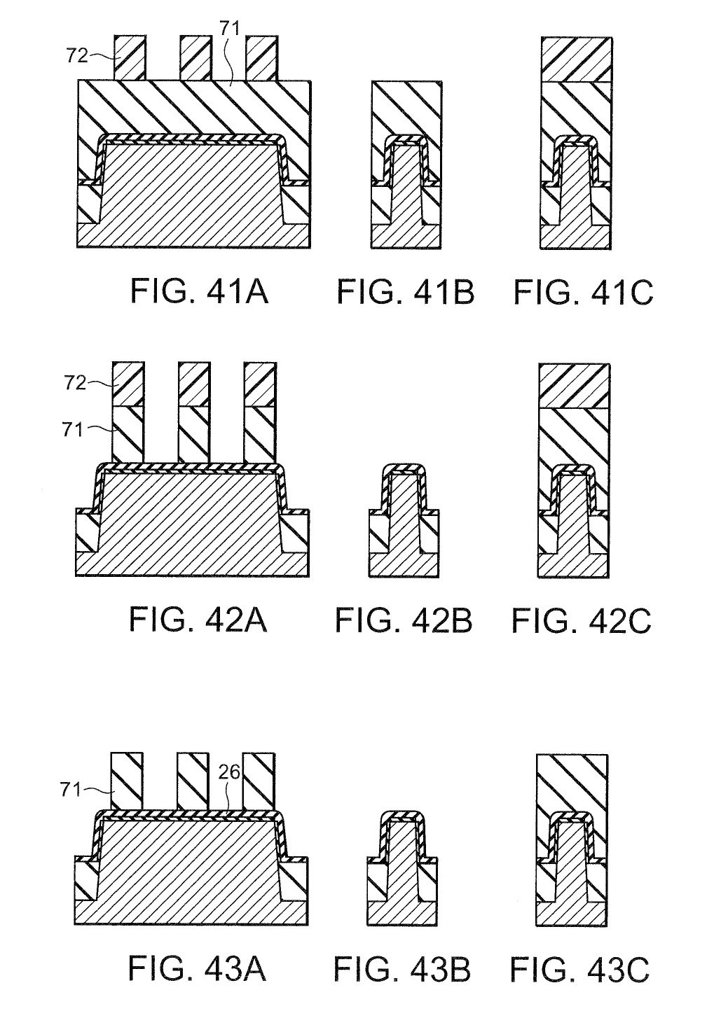

Next, as illustrated in FIGS. 41A, 41B and 41C, a resist pattern 72 is formed to define openings for gate electrode regions of the fin FETs and for dummy gate regions using known lithography technique. In this event, a space between stripes of the resist pattern 72 is equal to 45 nm, for example.

Next, as illustrated in FIGS. 42A, 42B and 42C, the silicon oxide film 71 is etched using the resist pattern 72 as a mask. Thereafter, as illustrated in FIGS. 43A, 43B and 43C, the resist pattern 72 is removed.

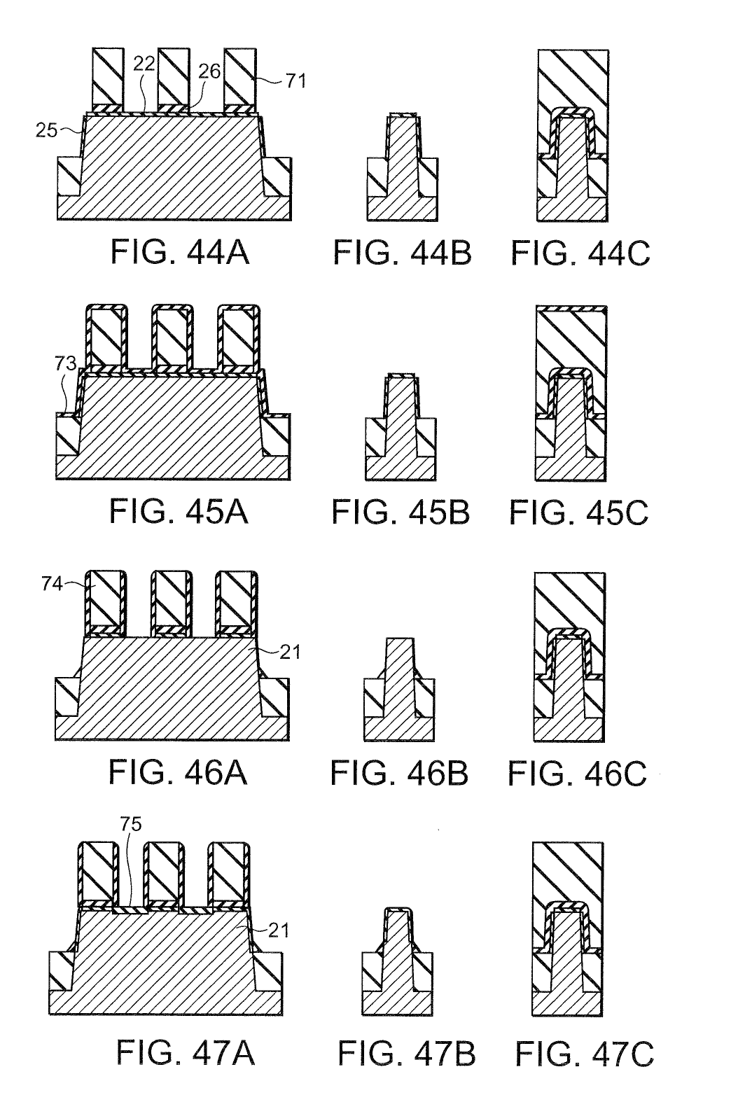

Next, as illustrated in FIGS. 44A, 44B and 44C, the silicon nitride film 26 is processed by anisotropic etching using the silicon oxide film 71 as a mask.

Next, as illustrated in FIGS. 45A, 45B and 45C, a silicon nitride film 73 (e.g. 10 nm thickness) is deposited on the entire surface. Then, the silicon nitride film 73 is processed by anisotropic etching to form sidewalls 74 in the form of the silicon nitride film 73 on side walls of the silicon oxide films 71. In this event, a part of the gate dielectric film 22 and the silicon oxide film 25 are also removed. Thus, openings corresponding to channel portions are formed in the gate dielectric film 22, the silicon oxide film 25 and the silicon nitride film 73 which covers the surface of the fin portion.

Next, as illustrated in FIGS. 47A, 47B and 47C, thermal oxide films 75 (e.g. 10 nm thickness each) are formed on exposed surfaces of the silicon substrate 21 by thermal oxidization.

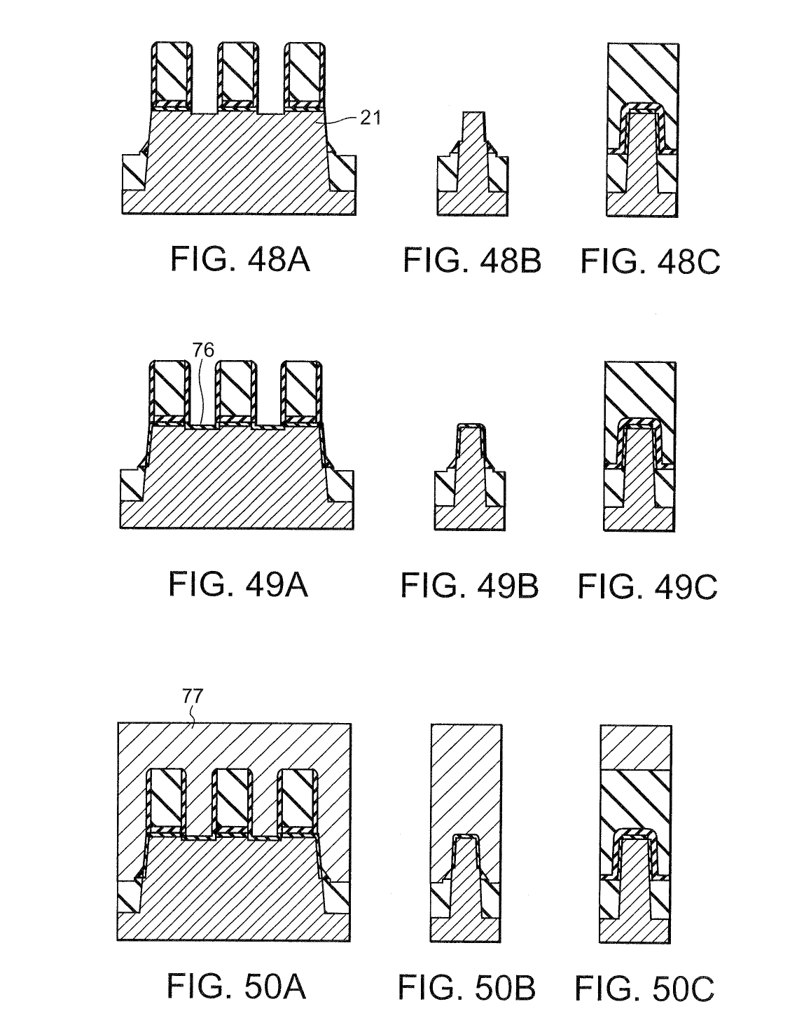

Next, as illustrated in FIGS. 48A, 48B and 48C, the thermal oxide films 75 are removed by chemical dry etching or diluted hydrofluoric acid. Hereby, width of the channel portions of the active region can be selectively narrowed than widths of the storage node contact portions and width of the bit line contact portion.

Next, as illustrated in FIGS. 49A, 49B and 49C, the exposed surfaces of the silicon substrate 21 in the openings are oxidized to form gate oxide films 76 (e.g. 6 nm thickness each). Then, the surfaces of the gate oxide films 76 in the openings are changed into oxynitride films (e.g. 3 nm thickness each) by an azotizing process using plasma. Incidentally, high temperature oxide (HTO) films or high dielectric constant films may be used as a substitute for the gate oxide films 76 and the oxynitride films.

Next, as illustrated in FIGS. 50A, 50B and 50C, a gate electrode polysilicon layer 77 is deposited, for example, by 100 nm. Additionally, it is preferable that the polysilicon layer 77 includes boron, which is doped therein, of 2E20 cm⁻³ (in-situ) or more.

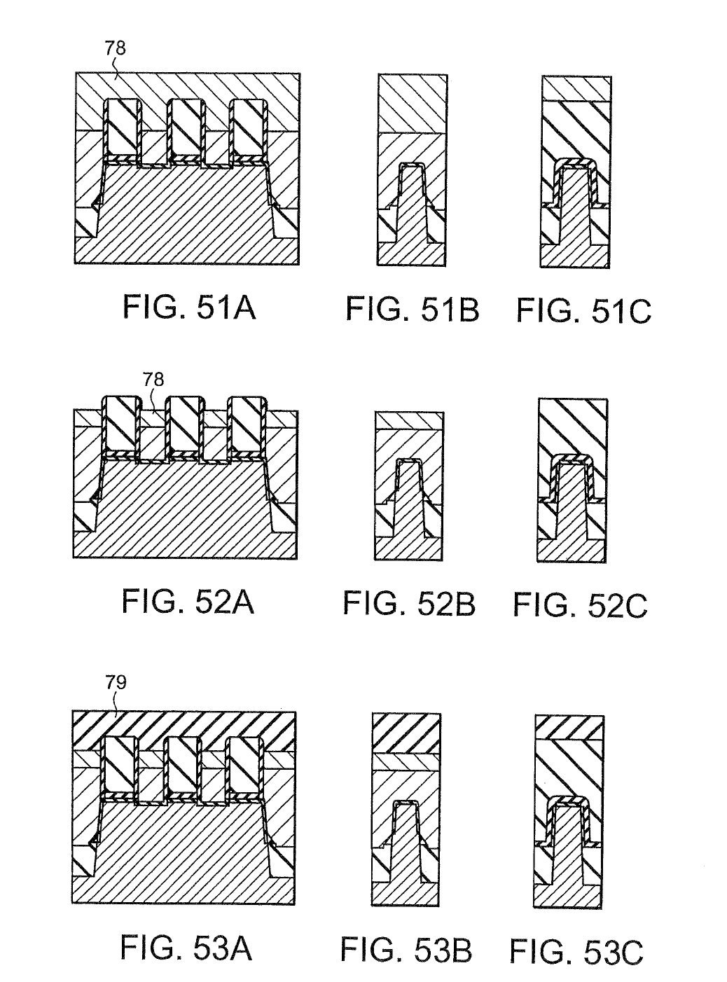

Next, the polysilicon layer 77 is dry etched back to have a predetermined thickness (e.g. 50 nm) at the upside of the gate electrode formation regions. Then, as illustrated in FIGS. 51A, 51B and 51C, a stacked film 78 consisting of a tungsten silicide film (e.g. 5 nm thickness), a tungsten nitride film (e.g. 10 nm thickness) and a tungsten film (e.g. 55 nm thickness) is formed.

Next, as illustrated in FIGS. 52A, 52B and 52C, the stacked film 78 is dry etched back to have a thickness, for example, of 60 nm at the gate electrode formation regions.

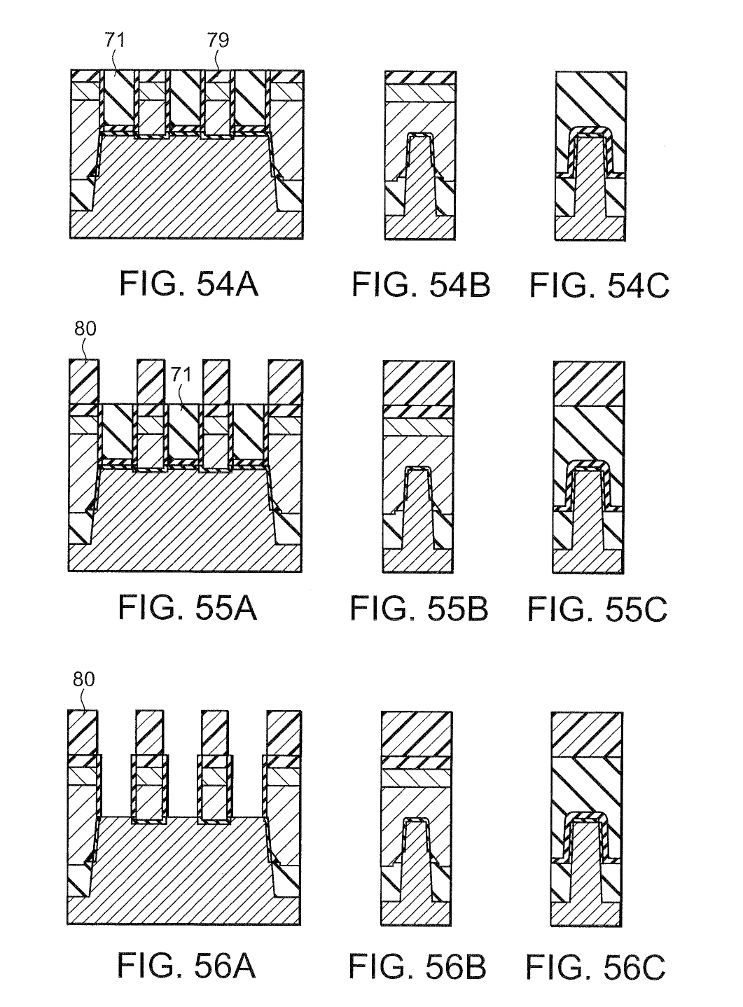

Next, as illustrated in FIGS. 53A, 53B and 53C, a silicon nitride film 79 (e.g. 100 nm thickness) is deposited. Then, as illustrated in FIGS. 54A, 54B and 54C, the silicon nitride film 79 is polished to expose the silicon oxide films 71 by CMP.

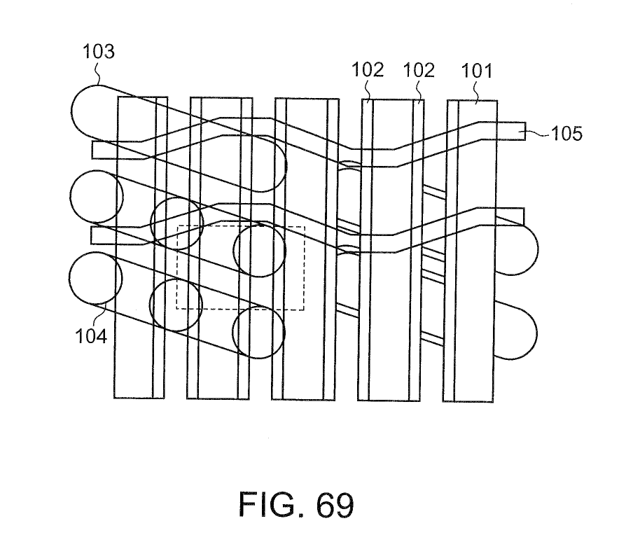

Next, as illustrated in FIGS. 55A, 55B and 55C, a resist pattern 80 is formed to have openings at portions corresponding to substrate contacts (i.e. the storage node contact portions and the bit line contact portion, see FIG. 69).

Next, as illustrated in FIGS. 56A, 56B and 56C, the silicon oxide films 71 are processed by anisotropic dry etching using the photo resist 80 as a mask. In this event, it is desirable that an etching selectivity of the silicon oxide film 71 to a silicon nitride film is equal to 15 or more. After the silicon oxide films 71 in the openings of the photo resist 80 are removed, by continuing the anisotropic dry etching, the silicon nitride film 26 and the gate dielectric film 22 are removed and thereby exposing the surfaces of the substrate 21 to the outside in the openings.

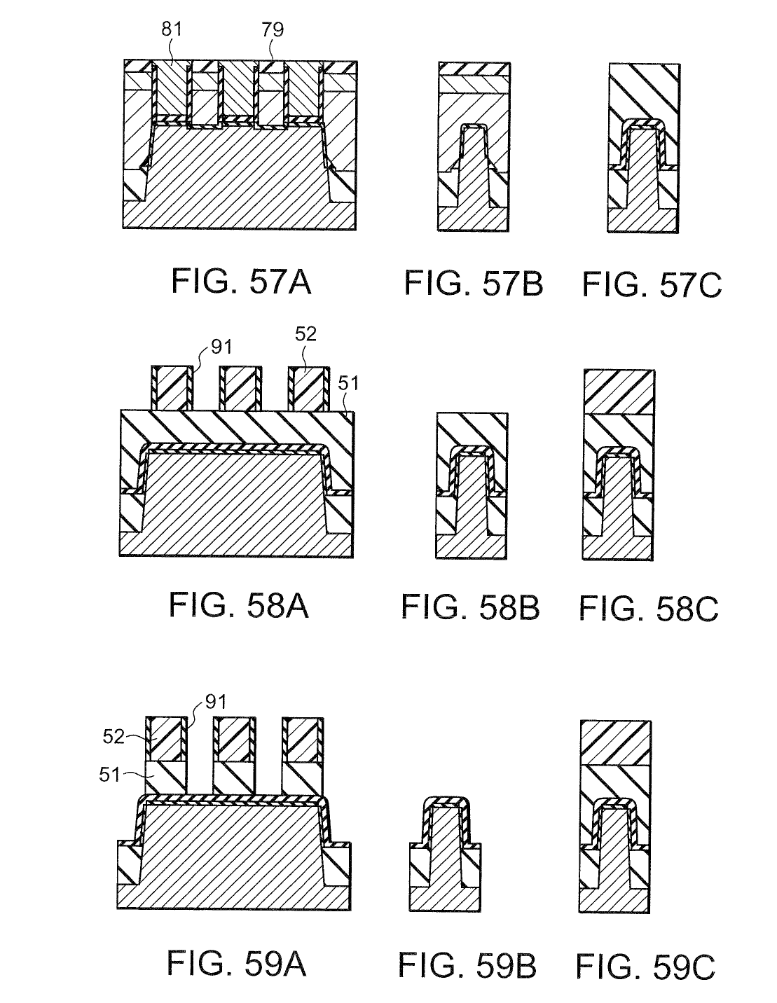

Next, as illustrated in FIGS. 57A, 57B and 57C, the resist pattern 80 is removed. Subsequently, a polysilicon layer 81 is deposited, for example, by 200 nm and then etched back to expose the silicon nitride films 79. For example, the polysilicon layer 81 includes phosphorus, which is doped therein, of 1E20 cm⁻³ (in-situ).

After that, known processes for a DRAM are performed to form capacitors and wiring lines or the like and thereby completing the DRAM.

As mentioned above, according to the third embodiment, it is possible to manufacture a semiconductor device (DRAM) in the same way as the first or the second embodiment. The semiconductor device has a fin FET with an active region in which a storage node contact portion and a bit line contact portion are lager than a channel portion in width. Hereby, there is obtained a semiconductor device (or a DRAM having twin cells) having a fin FET in which the channel portion can be fully depleted and sufficient on current can flow therethrough. Moreover, the manufacturing cost hardly rises.

Referring to FIGS. 58A to 68C, the description will be made about a forth embodiment of this invention.

At first, the state of FIGS. 26A-26C is obtained by performing the same processes as those (shown FIGS. 2A-8C and 25A-26C) of the second embodiment.

Subsequently, as illustrated in FIGS. 58A, 58B and 58C, sidewalls 91 (e.g. 10 nm thickness each) are formed on side walls of the stripes of the resist pattern 52 by RELACS (Resist Enhancement Lithography Assisted by Chemical Shrink). The sidewalls 91 serves for reducing length (in a right and left direction of FIG. 58A) of channels formed later. The same effect can be achieved by other sidewalls which are formed as follows. That is, the other sidewalls are formed by etching the silicon oxide film 51 using the resist pattern 52 as a mask, removing the resist pattern 52, and forming oxide films or silicon nitride films as the other sidewalls on the side walls of the remaining parts of the silicon oxide film 51.

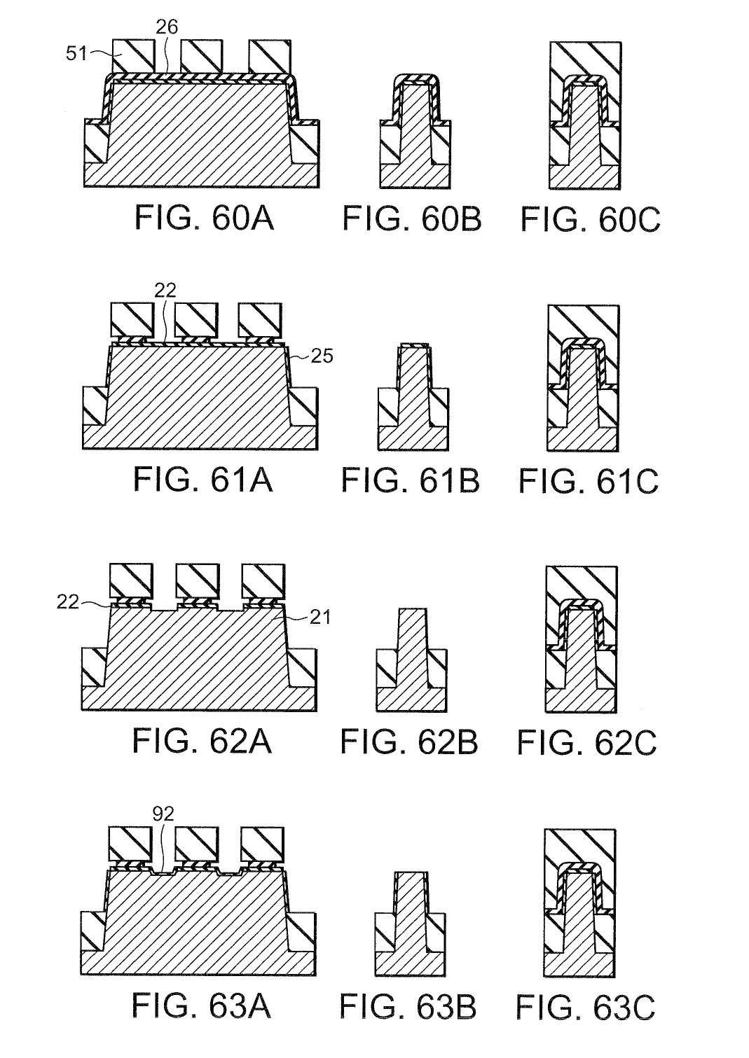

Next, as illustrated in FIGS. 59A, 59B and 59C, the silicon oxide film 51 is processed by anisotropic etching using the resist pattern 52 and the sidewalls 91 as a mask. Then, as illustrated in FIGS. 60A, 60B and 60C, the resist pattern 52 and the sidewalls 91 are removed.

Next, as illustrated in FIGS. 61A, 61B and 61C, the silicon nitride film 26 is etched, for example, by 30 nm or more by isotropic etching. Then, as illustrated in FIGS. 62A, 62B and 62C, the gate oxide film 22 and the silicon oxide film 25 in the openings are removed. Thus, openings are formed at the portions corresponding to the channel portions in the gate dielectric film 22, the silicon oxide film 25 and the silicon nitride film 26 which are cover the surface of the fin portion. Furthermore, exposed parts of the silicon substrate 21 in the opening are etched, for example, by 10 nm depth by isotropic etching. Hereby there is obtained a structure that widths of the channel portions of the active region are smaller than widths of the storage node contact portions and the bit line contact portion.

Next, as illustrated in FIGS. 63A, 63B and 63C, gate oxide films 92 (e.g. 6 nm thickness each) are formed on the exposed surfaces of the silicon substrate 21 by thermal oxidation. Then, the surfaces of the gate oxide films 92 are changed into oxynitride films (e.g. 3 nm thickness each) by an azotizing process using plasma. Incidentally, high temperature oxide (HTO) films or high dielectric constant films may be used as a substitute for the gate oxide films 92 and the oxynitride films.

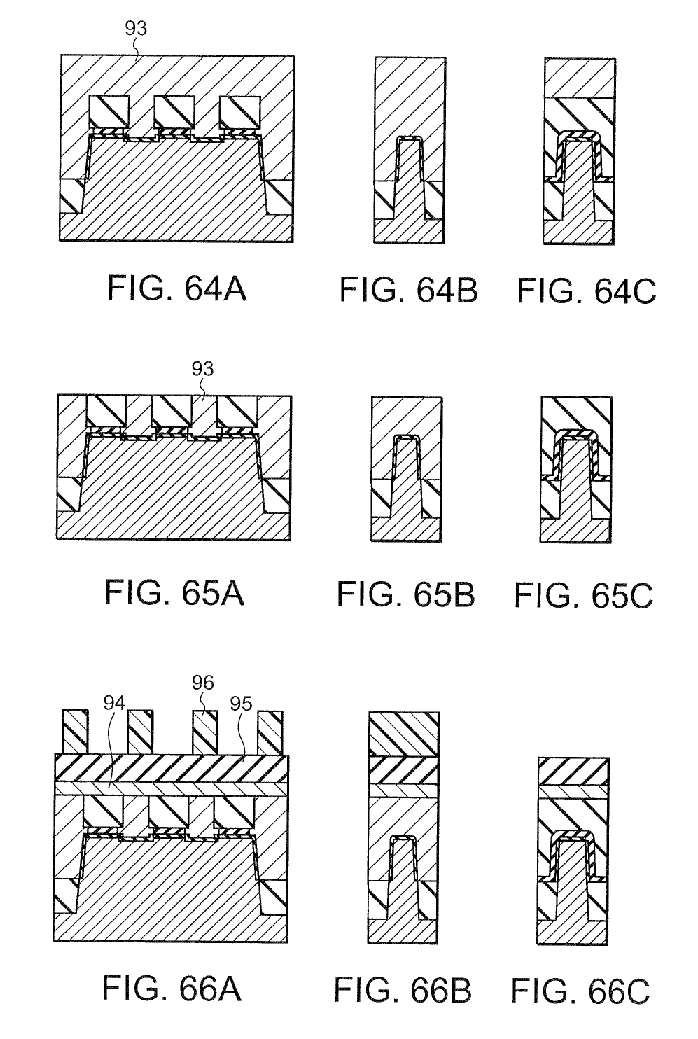

Next, as illustrated in FIGS. 64A, 64B and 64C, a gate electrode polysilicon layer 93 is deposited, for example, by 100 nm. Additionally, it is preferable that the polysilicon layer 93 includes boron, which is doped therein, of 2E20 cm⁻³ (in-situ) or more.

Next, as illustrated in FIGS. 65A, 65B and 65C, the polysilicon layer 93 is polished to expose the silicon oxide films 51 by CMP.

Next, as illustrated in FIGS. 66A, 66B and 66C, a stacked film 94 consisting of a tungsten silicide film (e.g. 5 nm thickness), a tungsten nitride film (e.g. 10 nm thickness) and a tungsten film (e.g. 55 nm thickness) and a silicon nitride film 95 (e.g. 100 nm) are disposed. Furthermore, by known lithography technique, a resist pattern 96 is formed at portions corresponding to the gate electrode portions and the dummy gate potions on the silicon nitride film 95.

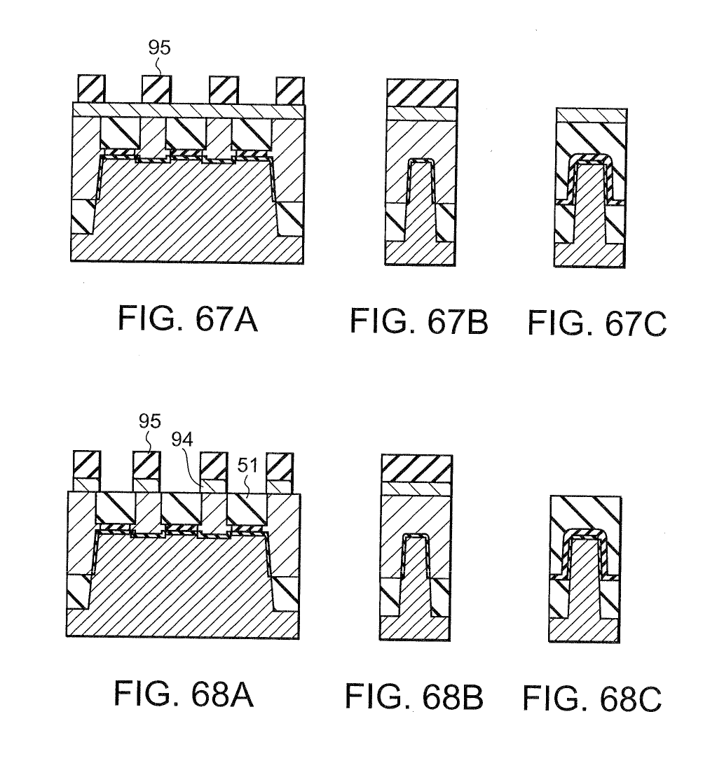

Next, as illustrated in FIGS. 67A, 67B and 67C, the silicon nitride film 95 is etched using the resist pattern 96 as a mask and then the photo resist 96 is removed.

Next, as illustrated in FIGS. 68A, 68B and 68C, the stacked film 94 consisting of the tungsten film, the tungsten nitride film and the tungsten silicide film is etched using the silicon nitride film 95 as a mask.

After that, known processes for a DRAM are performed to form capacitors and wiring lines or the like and thereby completing the DRAM.

As mentioned above, according to the third embodiment, it is possible to manufacture a semiconductor device (DRAM) in the same way as the first, the second or the third embodiment. The semiconductor device has a fin FET with an active region in which a storage node contact portion and a bit line contact portion are lager than a channel portion in width. Hereby, there is obtained a semiconductor device (or a DRAM having twin cells) having a fin FET in which the channel portion can be fully depleted and sufficient on current can flow therethrough. Moreover, the manufacturing cost hardly rises.

Aforementioned methods for manufacturing semiconductor devices are applicable to manufacturing a DRAM having 6F² memory cell structure. FIG. 69 shows a plan layout of the 6F² memory cell structure.

In FIG. 69, transfer gates 101 are arranged to be parallel with one another at predefined pitches of 2F (F: feature size) and to extend in an up and down direction of the figure. On both side walls of the transfer gate 101, light doped drain (LDD) sidewalls 102 are formed. Active regions 103 are arranged to be traversed by two adjacent transfer gates each. Moreover, two adjacent rows of the active regions 103 are placed on both sides of a dummy gate which is one of the transfer gates 101. Substrate contacts 104 to be connected to storage node contact portions or bit line contact portions are formed above the active regions 103 (at a front side of the figure). Bit lines 105 are arranged in a direction roughly perpendicular to the transfer gates 101 at the predefined pitches of 2F. Specifically, each bit line 105 passes upper sides of the bit line contact portions and avoids upper sides of the storage node contact portions. Arrangement of the transfer gates 101, the active regions 103 and bit lines 105 is a repeated pattern of a structure pattern for a basic region, which is framed by a broken line, of 2F×3F=6F².

Although the present invention has been described based on its preferred embodiments, it is to be understood that the present invention is not limited to the embodiments but may be otherwise variously embodied within the scope and sprit of the invention. These modifications and variations should be considered to be within the scope of the invention. For example, the methods of this invention can be applied to not only a DRAM but also other various semiconductor devices.

What is claimed is:

1. A semiconductor device comprising:
an active region having a fin shape; wherein
a width of a portion to be a channel portion of the active region is smaller than widths of portions to be source and drain of the active region.

2. A semiconductor device as claimed in claim 1, wherein the channel portion allows to be fully depleted.

3. A semiconductor device as claimed in claim 1, wherein the channel portion is one of two channel portions formed in the active region.

4. A semiconductor device as claimed in claim 1, wherein the active region is one of plural active regions arranged.

5. A semiconductor device as claimed in claim 4, wherein the active region is for a cell transistor of a dynamic random access memory.

6. A semiconductor device as claimed in claim 5, wherein the cell transistor is one of cell transistors arranged in a 6F² layout structure.

7. A method for manufacturing a semiconductor device having an active region of a fin shape, comprising the steps of:
forming a fin portion having a fixed width to be the active region; and
partly reducing a width of a portion to be a channel portion of the fin portion.

8. A method as claimed in claim 7, wherein the partly reducing step comprises the steps of:
selectively forming an opening at a portion corresponding to the channel portion in an oxide film and a nitride film which cover the fin portion;
selectively oxidizing an exposed surface of the fin portion in the opening to form an oxide film; and
removing the oxide film formed on the exposed surface of the fin portion to partly reduce the width of the fin portion.

9. A method as claimed in claim 7, wherein the reducing step comprises the steps:
selectively forming an opening at a portion corresponding to the channel portion in a oxide film and a nitride film which cover the fin portion; and
selectively etching an exposed surface of the fin portion in the opening to partly reduce the width of the fin portion.
